(19) United States
(12) Patent Application Publication
(10) Pub. No.: US 2026/0101547 A1
(43) Pub. Date: Apr. 9, 2026

(54) TWO-STEP OXIDE TRENCH SILICON CARBIDE MOSFET

(71) Applicant: Renesas Electronics Corporation, Tokyo (JP)

(72) Inventors: Meng Chia LEE, Milpitas, CA (US); Dilip Madhav RISBUD, Milpitas, CA (US)

(73) Assignee: Renesas Electronics Corporation, Tokyo (JP)

(21) Appl. No.: 18/909,424

(22) Filed: Oct. 8, 2024

(51) Int. Cl. H01L 29/06; H01L 21/02; H01L 21/04; H01L 29/16; H01L 29/423; H01L 29/66; H01L 29/78

(52) U.S. Cl. CPC H10D 62/109; H10D 12/031; H10D 30/668; H10D 62/8325; H10D 64/01366; H10D 64/516; H10P 30/22; H10P 70/20

(57) ABSTRACT

Semiconductor devices and processes for manufacturing semiconductors are described. A semiconductor device can include a drift region formed on a Silicon Carbide substrate. The semiconductor device can include a trench that penetrates through a source region and a channel and reaches the drift region. The semiconductor device can include an oxide region lining the trench. The oxide region can include a bottom portion, a lower side portion and an upper side portion. A thickness of the bottom portion and a thickness of the lower side portion can be greater than a thickness of the upper side portion. The semiconductor device can include a gate electrode formed in the trench lined with the oxide region. The semiconductor device can include a shield region in contact with a bottom portion of the trench. A width of the semiconductor region can be less than or equal to a width of the trench.

### BACKGROUND

The present disclosure relates in general to semiconductor devices, more particularly, to a Silicon Carbide (SiC) device that includes a two-step oxide trench.

A metal-oxide-semiconductor field-effect transistor (MOSFET) cell can be a planar MOSFET or a trench MOSFET. When compared to planar MOSFETs, the trench structure in a trench MOSFET helps in achieving a more efficient control of the depletion region. By etching a trench vertically into the substrate and lining it with gate oxide and a conductive material (typically polysilicon), the trench MOSFET can also achieve a higher packing density and reduce on-resistance compared to planar MOSFETs. The trench structure also helps in minimizing parasitic capacitances and improving thermal management. In an aspect, when Silicon Carbide (SiC) is used for forming the trench MOSFET, breakdown voltage is increased compared to Silicon (Si) trench MOSFETs because SiC has a larger bandgap than silicon (Si).

### SUMMARY

In one embodiment, a semiconductor device can be generally described. The semiconductor device can include a semiconductor substrate of a first conductivity type. The semiconductor substrate can be formed by Silicon Carbide (SiC). The semiconductor device can further include a drift region of the first conductivity type formed on the semiconductor substrate. The semiconductor device can further include a channel of a second conductivity type opposite to the first conductivity type formed on the drift region. The semiconductor device can further include a source region of the first conductivity type formed on the channel. The semiconductor device can further include a trench that penetrates through the source region and the channel layer and reaches the drift region. The semiconductor device can further include an oxide region that lines the trench. The oxide region can include a bottom portion, a lower side portion and an upper side portion. A thickness of the bottom portion can be greater than a thickness of the upper side portion. A thickness of the lower side portion can be greater than the thickness of the upper side portion. A gate electrode can be formed in the trench lined with the oxide region. The semiconductor device can further include a shield region of the second conductivity in contact with the bottom portion of the trench and a width of the shield region can be less than or equal to a width of the trench.

In one embodiment, a semiconductor device can be generally described. The semiconductor device can include a semiconductor substrate of a first conductivity type. The semiconductor substrate can be formed by Silicon Carbide (SiC). The semiconductor device can further include a drift region of the first conductivity type formed on the semiconductor substrate. The semiconductor device can further include a channel of a second conductivity type opposite to the first conductivity type formed on the drift region. The semiconductor device can further include a source region of the first conductivity type formed on the channel. The semiconductor device can further include a trench that penetrates through the source region and the channel layer and reaches the drift region. The semiconductor device can further include an oxide region that lines the trench. The oxide region can include a bottom portion, a lower side portion and an upper side portion. A thickness of the bottom portion can be greater than a thickness of the upper side portion. A thickness of the lower side portion can be greater than the thickness of the upper side portion. At least one gate electrode can be formed in the trench lined with the oxide region. The semiconductor device can further include a shield region of the second conductivity in contact with the bottom portion of the trench and a width of the shield region can be less than or equal to a width of the trench.

In one embodiment, a method for manufacturing a semiconductor device is generally described. The method can include forming a first oxide layer having a first thickness to line a trench formed in a Silicon Carbide (SiC) substrate. The method can further include forming a conductive material on a bottom portion of the trench lined with the first oxide layer. The method can further include forming a nitride layer above the conductive material and along sidewalls of the trench. The method can further include etching the conductive material using the nitride layer as hardmask. The method can further include conducting a first oxidation process on a remaining portion of the conductive material to form a bottom portion and a lower side portion of an oxide region within the trench. The method can further include removing the nitride layer and cleaning exposed sidewalls of the trench. The method can further include conducting a second oxidation process on the exposed sidewalls of the trench to form an upper side portion of the oxide region. The method can further include forming a gate electrode in the trench lined with the oxide region.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example of a portion of a two-step oxide trench Silicon Carbide MOSFET in one embodiment.

FIG. 2 illustrates an example of a two-step oxide trench Silicon Carbide MOSFET in one embodiment.

FIG. 3 illustrates an example of an oxide region in a two-step oxide trench Silicon Carbide MOSFET in one embodiment.

FIG. 4A illustrates a step in a manufacturing process of a two-step oxide trench Silicon Carbide MOSFET in one embodiment.

FIG. 4B illustrates another step in a manufacturing process of a two-step oxide trench Silicon Carbide MOSFET in one embodiment.

FIG. 5A illustrates another step in a manufacturing process of a two-step oxide trench Silicon Carbide MOSFET in one embodiment.

FIG. 5B illustrates another step in a manufacturing process of a two-step oxide trench Silicon Carbide MOSFET in one embodiment.

FIG. 6A illustrates another step in a manufacturing process of a two-step oxide trench Silicon Carbide MOSFET in one embodiment.

FIG. 6B illustrates another step in a manufacturing process of a two-step oxide trench Silicon Carbide MOSFET in one embodiment.

FIG. 7A illustrates another step in a manufacturing process of a two-step oxide trench Silicon Carbide MOSFET in one embodiment.

FIG. 7B illustrates another step in a manufacturing process of a two-step oxide trench Silicon Carbide MOSFET in one embodiment.

FIG. 8A illustrates another step in a manufacturing process of a two-step oxide trench Silicon Carbide MOSFET in one embodiment.

FIG. 8B illustrates another step in a manufacturing process of a two-step oxide trench Silicon Carbide MOSFET in one embodiment.

FIG. 8C illustrates another step in a manufacturing process of a two-step oxide trench Silicon Carbide MOSFET in one embodiment.

FIG. 9A illustrates another example of a two-step oxide trench Silicon Carbide MOSFET in one embodiment.

FIG. 9B illustrates another step in a manufacturing process of a two-step oxide trench Silicon Carbide MOSFET in one embodiment.

FIG. 9C illustrates another step in a manufacturing process of a two-step oxide trench Silicon Carbide MOSFET in one embodiment.

FIG. 9D illustrates another step in a manufacturing process of a two-step oxide trench Silicon Carbide MOSFET in one embodiment.

FIG. 9E illustrates another step in a manufacturing process of a two-step oxide trench Silicon Carbide MOSFET in one embodiment.

FIG. 10 is a flow diagram illustrating a process to manufacture a two-step oxide trench Silicon Carbide MOSFET in one embodiment.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

A trench gate metal-oxide-semiconductor field-effect transistor (MOSFET) can handle significant power and provide a high-power drive capability by vertically conducting current from a top surface to a bottom surface of a semiconductor die. The trench gate MOSFET in its active region can include a large number of parallel connected active trench gate MOSFET cells each including a trench formed in the semiconductor die, with each active trench having surrounding source regions and oppositely-doped body regions, and the trenches can be deep enough to cross through the body regions to a drift region below the top surface of the semiconductor die. Each active trench gate cell has a gate buried in the trench that can include a gate electrode including doped polysilicon and a gate dielectric. The gate electrodes, when appropriately biased, can control the current conduction in the body region and enable the MOSFET cells to be turned on, thus enabling current to flow between the source and the drain from top to bottom.

Silicon Carbide (SiC) devices, when compared to Silicon (Si) devices, can provide higher breakdown voltage and withstand higher voltages. Thus, SiC devices, instead of Si devices, may be more suitable for high-power applications where high breakdown voltages are required. SiC devices also have lower ON-Resistance (RDSon) when compared to Si devices, and lower RDSon can lead to less conduction losses, thus improving efficiency. SiC devices can also operate at higher temperatures and have desirable switching characteristics (e.g., higher switching frequencies) when compared to Si devices. However, manufacturing processes for Si devices cannot be used for manufacturing SiC devices. For example, the hardness of SiC is greater than the hardness of Si, hence processes typically used for Si devices may not be applicable to SiC devices.

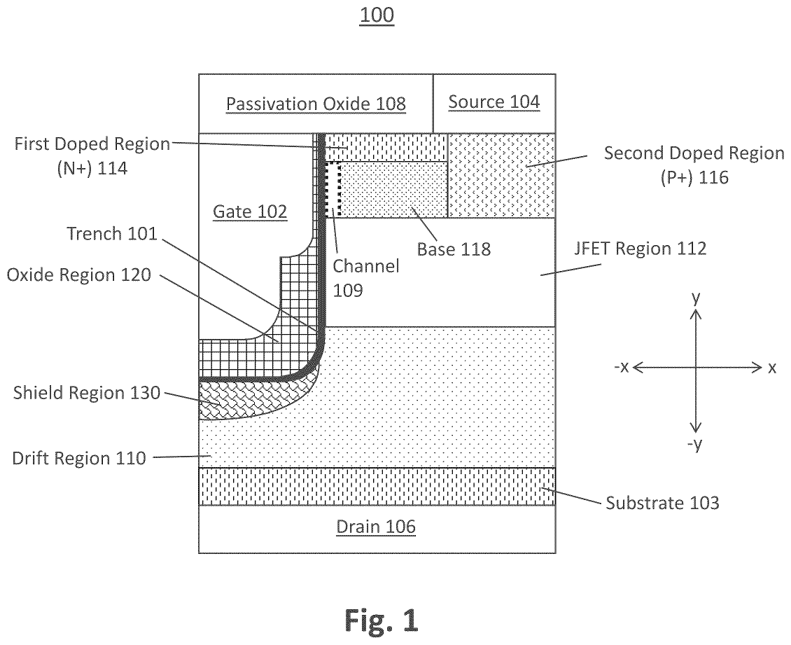

FIG. 1 illustrates a side view of an example of a portion of a two-step oxide trench Silicon Carbide MOSFET in one embodiment. A side view of a portion of a semiconductor device 100, or device 100 herein, is shown in FIG. 1. Device 100 can be formed using a substrate 103 that includes a gate region 102 (or gate electrode, herein “gate 102”), a source terminal 104 (herein “source 104”), a drain terminal 106 (herein “drain 106”), a layer of passivation oxide 108, a drift region 110, a junction field effect transistor (JFET) region 112, a first doped region 114, a second doped region 116, a base 118, an oxide region 120 and a shield region 130. Substrate 103 can be a semiconductor substrate that is doped with impurities of a first type, such as N-type impurities, such that substrate 103 is of a first conductivity type. In the descriptions herein, the first conductivity type can be either N-type or P-type and a second conductivity type can have opposite conductivity from the first conductivity type. For example, when the first conductivity type is N-type, second conductivity type is P-type, and vice versa.

Device 100 can be a SiC trench MOSFET. In one embodiment, device 100 can be one SiC trench MOSFET among a plurality of SiC trench MOSFETs in an integrated circuit. The trench MOSFET can be formed by etching a trench 101 vertically (e.g., in the-y direction) into a SiC substrate (e.g., substrate 103) and doping the remaining SiC substrate with impurities of different types and/or concentrations. Walls of trench 101 can be lined with a layer of gate oxide (e.g., oxide region 120, which will be further described below), and the lined trench 101 can be filled with a conductive material, such as polysilicon, forming the gate 102. Source 104 can be a region of the first conductivity type and drain 106 can be a region of the first conductivity type. Passivation oxide 108 can be a layer of oxide that is deliberately formed to function as a barrier to protect device 100 from environmental factors such as moisture, chemicals, and environmental pollutants that could compromise functionality of device 100.

Drift region 110 can be located between base 118 and substrate 103, and can extend along the walls of the trench 101 where gate 102 is located. Drift region 110 can be a region where carriers (e.g., electrons or holes) can drift from the source 104 to the drain 106. When a voltage is applied to the gate 102, an electric field is generated to form an inversion layer in a channel region (hereinafter “channel”) 109. In an embodiment, the channel 109 can be of the second conductivity type and have a dopant concentration varying between approximately 1×10¹⁵ cm⁻³ and 1×10¹⁸ cm⁻³. In some embodiments, impurities of the first type can be used to form channel 109, enabling N-channel depletion mode MOSFET operations. The electric field can direct the carriers to move towards the drain 106, thus allowing current to flow from source 104 to drain 106. The strength and distribution of the electric field in drift region 110 can impact various electrical characteristics, such as on-resistance (RDSon), breakdown voltage, or other characteristics of device 100.

Device 100 can further include JFET region 112 formed within drift region 110 that provides a direct junction between the gate 102 and the channel 109. In an embodiment, the JFET region 112 can be located between a top surface of drift region 110, adjacent to trench 101, and bottom surfaces of channel 109, base 118 and second doped region 116. In some instances, JFET region 112 can be formed with a higher donor doping of the first conductivity type that can vary between, for example, 1×10¹⁶ cm⁻³ and 1×10¹⁸ cm⁻³.

First doped region 114 can be a region that is doped with impurities of a first type, such as N-type impurities. Second doped region 116 can be a region that is doped with impurities of a second type, such as P-type impurities. First doped region 114 can have the first conductivity type and second doped region 116 can have the second conductivity type. First doped region 114 and second doped region 116 can be in contact with source 104. First doped region 114 can be in contact with passivation oxide 108. When device 100 is an N-type device, first doped region 114 can be referred to as a first doped region and second doped region 116 can be referred to as a second doped region. In some aspects, first doped region 114 can also be referred to as the heavily doped region. If the first conductivity type is N-type, then first doped region 114 can be created by, for example, ion implantation or diffusion where N-type dopants such as Phosphorus (P) or Arsenic (As) are implanted into the region that eventually become first doped region 114. If the first conductivity type is N-type, then second doped region 116 can be created by, for example, ion implantation or diffusion where P-type dopants such as Boron (B), Aluminum (Al) or Gallium (Ga) are implanted into the region that eventually become second doped region 114. The depth and doping concentration of first doped region 114 and the second doped region 116 can be controlled to define the RDSon and breakdown voltage of device 100. For example, a doping concentration of the first dope region 114 can be of approximately 1×10¹⁹ cm⁻³ to approximately 1×10²¹ cm⁻³, while a doping concentration of second doped region 116 can be of approximately 1×10¹⁸ cm⁻³ to approximately 1×10²¹ cm⁻³.

Base 118 can be doped with impurities of the second type (e.g., same as second doped region 116), such as P-type impurities. The impurity concentration of impurities being used for doping base 118 can be less than the impurity concentration of second doped region 116. By having smaller impurity concentration than second doped region 116, base 118 can facilitate majority carriers injected from the emitter (e.g., source 104) to traverse the base 118 and reach the collector (e.g., drain 106). In an embodiment, a doping concentration of the base 118 can vary between approximately 1×10¹⁶ cm⁻³ to approximately 1×10¹⁸ cm⁻³. In some embodiments, base 118 can be lightly doped with impurities of the first type to achieve an accumulation-mode MOSFET (ACCUFET), in such cases the doping concentration of base 118 can vary between approximately 1×10¹⁴ cm⁻³ to approximately 1×10¹⁶ cm⁻³. In other embodiments, base 118 can be doped with impurities of the first type to achieve a depletion-mode MOSFET, in such cases the doping concentration of base 118 can vary between approximately 1×10¹⁶ cm⁻³ to approximately 1×10¹⁸ cm⁻³

In an aspect, the layer of oxide layer lining the trench 101, or gate oxide, can be an insulating material that separates the gate 102 from the semiconductor channel (e.g., channel 109) and other conductive layers or regions of device 100. The insulating material lining trench 101 can be, for example, Silicon Dioxide (SiO₂) or other high-k dielectrics. The layer of oxide can also help to control the flow of current between source 104 and drain 106 by modulating the electric field in drift region 110. A thinner layer of gate oxide can provide relatively more efficient control over the channel and a thicker layer of gate oxide can prevent gate oxide breakdown. The threshold voltage of device 100 can also be controlled by the thickness of the gate oxide. If the electric field in drift region 110 is too high, the gate oxide can degrade over time and negatively impact the overall lifespan and reliability of device 100. The oxide degradation can lead to shifts in the threshold voltage. For trench MOSFETs, the trench tends to have a relatively deeper profile (e.g., along the y-axis) compared to its width (e.g., x-axis). Thus, the electric field lines tend to concentrate at the bottom of the trench causing the electric field underneath the trench (e.g., −y direction) to be higher than other regions, such as near the sidewalls of the trench.

In some conventional devices, to mitigate the high electric field at the bottom of the trench, a P-shield, which is a P-type implant, can be positioned underneath the trench to mitigate the high electric field underneath the trench. However, the addition of the P-shield can compromise the ideal spread resistance. The spread resistance is the resistance encountered by current as the current spreads out from the gate to other regions of the device. As the area of contact between gate and other regions of the device increases, the spread resistance can be reduced, leading to lower RDSon and improving performance of the device. The addition of the P-shield can reduce the area of contact between gate and other regions of the device, thus increasing the spread resistance.

In some conventional devices, the bottom portion of the gate oxide lining the trench can be made to be thicker to reduce the electric field at the bottom of the trench. However, thermally growing a thick oxide in SiC can be challenging. For example, Silicon (Si) and Carbon (C) has strong covalent bonds that are difficult to break, making it challenging for oxygen to react with SiC and to form a stable oxide layer, and more energy is required to break the bonds to allow oxidation to occur. Further, SiC has thermal stability that can withstand high temperatures without degrading, thus it is less reactive to oxygen at high temperatures and requiring more aggressive conditions to form the oxide layer, and also making it difficult to achieve thicker and smoother oxide layer.

Also, conventional techniques to reduce electric field at the bottom of the trench does not alleviate the high electric field at the corner of the trench and the lower part of the trench's sidewalls. Some conventional techniques include extending the P-shield underneath the trench laterally (e.g., along the x-axis) to reduce electric field at the corner of the trench, but when the P-shield is wider extends past the gate oxide, the spread resistance increases. To be described in more detail below, device 100 can have a gate oxide labeled as oxide region 120 that has a bottom portion and a lower side portion that are thicker than an upper side portion, along with a P-shield labeled as shield region 130 that does not extend past the gate oxide in the lateral direction (e.g., does not extend past the trench sidewall). The oxide region 120 can be manufactured using a multi-step (e.g., two-step) process that independently controls the thicknesses of the bottom portion, the lower side portion and the upper side portion of oxide region 120. Further, due to the different thicknesses, specifically the thicker lower side portion of oxide region 120, the shield region 130 can be manufactured to have a width that does not extend past the gate oxide.

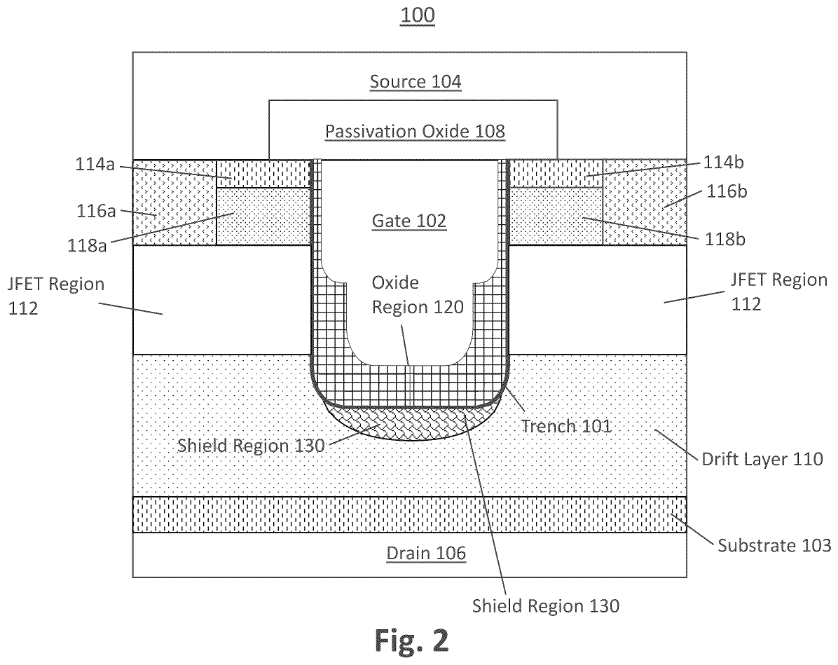

FIG. 2 illustrates an example of a two-step oxide trench Silicon Carbide MOSFET in one embodiment. Descriptions of FIG. 2 can reference components shown in FIG. 1. FIG. 2 shows a cross-sectional view of one whole unit, or one cell, of device 100 that implements a SiC trench MOSFET. As shown in FIG. 2, trench 101 is etched and formed between two first doped region regions 114a, 114b (e.g., first doped region), two second doped region regions 116a, 116b (e.g., second doped region) and two base regions 118a, 118b. Trench 101, in its entirety as shown in FIG. 2, can have a U shape and shield region 130 can span across the bottom portion of the trench 101 without extending past the sidewalls of trench 101. The oxide region 120 has a thick bottom portion, thick lower side portions on lower portions of the side of oxide region 120, and thin upper side portions on upper portions of the side of oxide region 120.

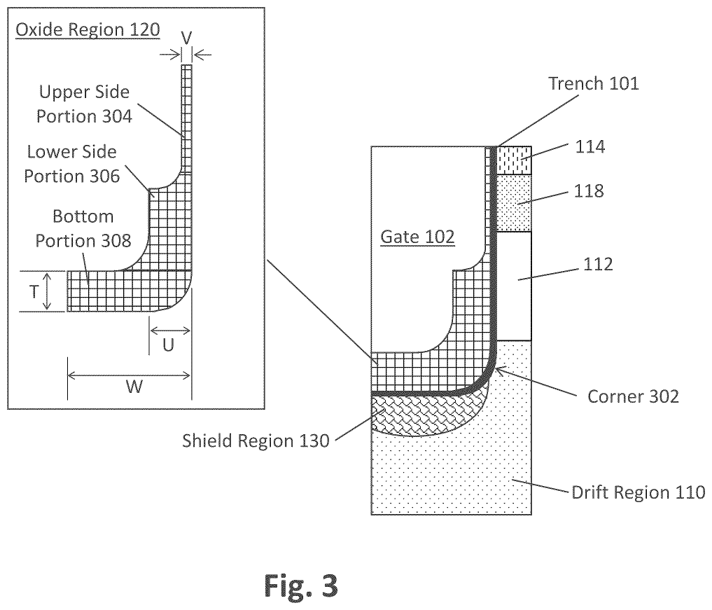

FIG. 3 illustrates an example of an oxide region 120 in a two-step oxide trench Silicon Carbide MOSFET in one embodiment. Description of FIG. 3 can reference components shown in FIG. 1 and FIG. 2. As shown in FIG. 3, oxide region 120 can include an upper side portion 304, a lower side portion 306 and a bottom portion 308. A thickness of upper side portion 304 is labeled as V. For example, thickness V can vary between approximately 1 nm to approximately 20 nm. A thickness of lower side portion 306 is labeled as U. For example, thickness U can vary between approximately 1 nm to approximately 500 nm. A thickness of bottom portion 308 is labeled as T. For example, thickness T can vary between approximately 1 nm to approximately 500 nm. The thickness U and the thickness T can be greater than the thickness V. The thickness U and T can be the same or can be different.

Bottom portion 308 can be in contact with shield region 130. Bottom portion 308 and shield region 130 can contribute to reduction of electric field in drift region 110 near the bottom of trench 101, such as underneath trench 101. Upper side portion 304 can be in contact with at least one of the first doped region 114, base 118 and JFET region 112. Lower side portion 306 can be in contact with JFET region 112 and drift region 110. Lower side portion 305 can contribute to reduction of electric field in drift region 110 near portions of the sidewalls of trench 101 and a corner 302 of trench 101. The utilization of lower side portion 306 to reduce electric field in drift region 110 near corner 302 can allow bottom portion 308 to have a width W that is less than or equal to a width of trench 101. In other words, bottom portion 308 does not need to be extended past a sidewall of trench 101 to reduce electric field near corner 302. Note that the width W of bottom portion 308 can be sized to not extend past the sidewalls of trench 101 and to be non-overlapping with corner 302.

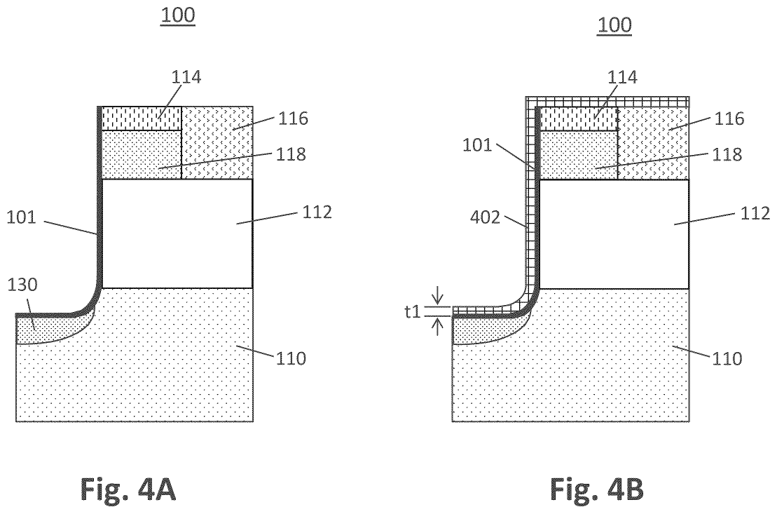

FIG. 4A to FIG. 8C illustrate a series of steps in a manufacturing process of a two-step oxide trench Silicon Carbide MOSFET in one embodiment. Descriptions of FIG. 4A to FIG. 8C can reference components shown in FIG. 1 to FIG. 3. In FIG. 4A, shield region 130 can be implanted into a stack comprising first doped region 114, second doped region 116, base 118 and drift region 110. Implantation of shield region 130 can include various techniques such as using a photomask or an implant mask to selectively block or allow the implantation of dopants of the second conductivity type (e.g., Aluminum) in the location of shield region 130 in drift region 110. By way of example, an ion implanter can be used for introducing ions of dopant material into the SiC lattice to create shield region 130 of the second conductivity type. Annealing can be performed to activate the dopants, repair damage to the substrate caused by the ion implantation, and to ensure that the dopants are properly incorporated into the lattice. In an embodiment, the shield region 130 can have a dopant concentration varying between approximately 1×10¹⁵ cm⁻³ and 5×10¹⁷ cm⁻³. A (vertical) depth of trench 101 into the drift region 110 (e.g., in the-y direction) can be of approximately 0.5 mm to approximately 10 mm, and preferably between approximately 0.5 mm to approximately 2 mm.

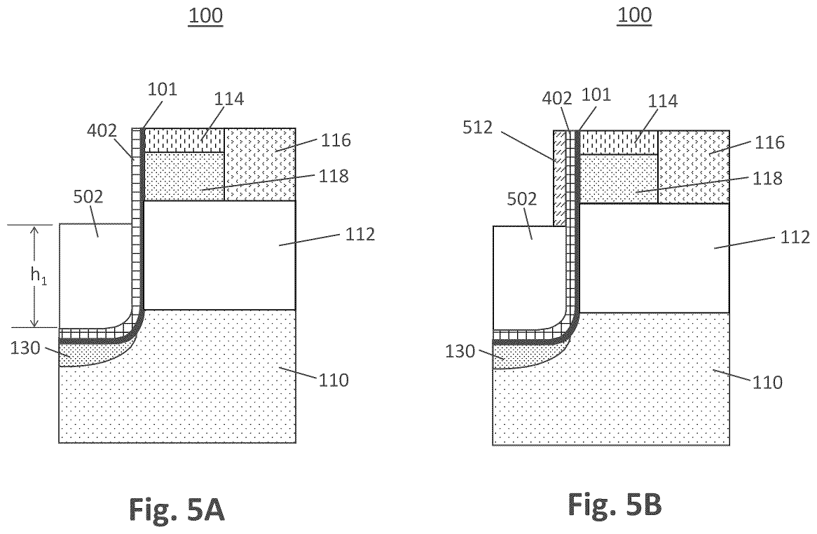

In FIG. 4B, after implanting shield region 130, a layer of oxide (hereinafter “oxide”) 402 having a thickness of t1 can be formed to line the walls of trench 101. The oxide 402 can be formed by thermal oxidation of an oxide material. However, in some embodiments, the oxide 402 can be formed by conformal deposition of the oxide material. The oxide 402 can be, for example, high-quality oxide that has relatively superior properties compared to other oxides in terms of purity, stability, or specific functional characteristics. The oxide 402 can be formed by oxides such as, for example, Silicon Dioxide (SiO₂). The duration of oxidation to form oxide 402 can be controlled to define the thickness t1. For example, the oxidation process can be controlled to achieve an oxide 402 having a thickness t1 varying between approximately 1 nm to approximately 500 nm. In some embodiments, a chemical mechanical planarization (CMP) process can be performed to remove excess oxide material (e.g., oxide 402) from upper surfaces of device 100 and create the smooth top surface depicted in FIG. 5A.

In FIG. 5A, after lining trench 101 with the oxide 402, a conductive material 502, such as polysilicon, can be deposited into the trench 101 lined with oxide 402. The conductive material 502 substantially fills a bottom portion of trench 101. In an embodiment, a thickness h₁ of the conductive material 502 deposited within trench 101 can be of approximately 0 mm to approximately 1 μm. However, the thickness h₁ of the conductive material 502 can vary based on the depth of the trench, ranging from 0% to 50% of the trench depth. The thickness h₁ of the conductive material 502 can determine a location of a topmost portion of the lower side portion 306 of oxide region 120 described below.

In FIG. 5B, a nitride layer 512 can be deposited within trench 101 along top portions of the oxide 402 not covered by the conductive material 502. As depicted in the figures, a bottom surface of the deposited nitride layer 512 can be in direct contact with a top surface of the conductive material 502. Formation of the nitride layer 512 can include depositing a nitride material (e.g., silicon nitride) using various deposition methods. In an exemplary embodiment, a thickness of the nitride layer 512 may vary between approximately 10 nm to approximately 500 nm. Nitride layer 512 can function as a hardmask layer during etching of conductive material 502.

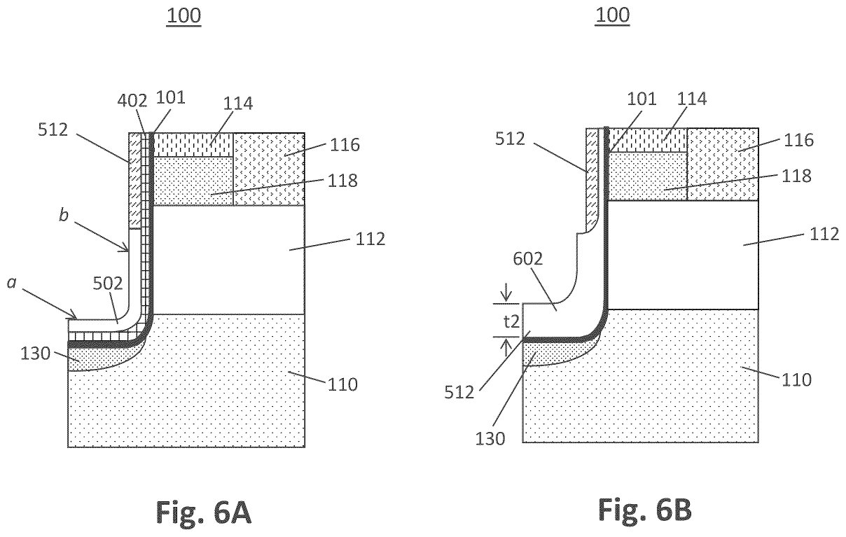

In FIG. 6A, the nitride layer 512 is used as hardmask to etch the conductive material 502. The conductive material 502 can be etched using various wet and dry etching techniques that selectively remove the conductive material 502 without removing the oxide 402 or the nitride layer 512. After the etching process, a first (horizontal) portion a of the conductive material 502 remains on the bottom portion of trench 101 lined with conductive material 502 and a second (vertical) portion b of the conductive material 502 remains on opposing sidewalls of trench 101 also lined with oxide 402. In an embodiment, the thickness of the nitride layer 512 can determine a thickness of the remaining portions of the conductive material 502 within trench 101.

In FIG. 6B, following the conductive material 502 etch process, the device 100 undergoes a first thermal oxidation process in which the polysilicon in conductive material 502 is oxidized to form, together with oxide 402, a layer of oxide (hereinafter “oxide”) 602 of different thicknesses that covers the bottom portion and sidewalls of trench 101. A thickness t2 of the oxide 602 formed on the bottom portion of trench 101 may vary between approximately 0 nm to 500 nm. The oxide 602 can be, for example, high-quality oxide that has relatively superior properties compared to other oxides in terms of purity, stability, or specific functional characteristics. The oxide 602 can be formed by oxides such as, for example, SiO₂.

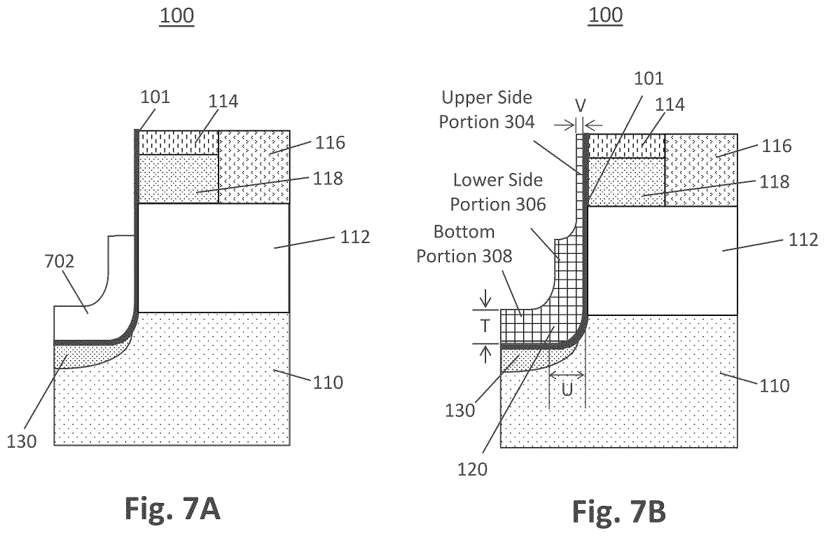

In FIG. 7A, the nitride layer 512 can be stripped from device 100 using any suitable technique including, for example, reactive ion etching (RIE). A cleaning process can be performed to clean top sidewalls of trench 101 after removing the nitride layer 512. A remaining portion 702 of the oxide 602 stays within trench 101 after the cleaning process. In FIG. 7B, a second thermal oxidation process can be performed on device 100 to form oxide region 120. During the second thermal oxidation process, an upper side portion 304 can be formed along exposed upper sidewalls of trench 101(i.e., sidewalls of trench 101 not covered by the remaining portion 702 of oxide 602). Accordingly, oxide region 120 can be formed by the combination of the remaining portion 702 of the oxide 602 and newly formed upper side portion 304 of oxide material that extends along upper sidewalls of trench 101 until a top surface of device 100. A duration of the second thermal oxidation process can be controlled such that a thickness V of the upper side portion 304 can vary between approximately 1 nm to approximately 20 nm.

Since the duration of the oxidation process to define thickness t1 of oxide 402 and to define thickness t2 of the layer of oxide 602 can be controlled independently, or in separate steps, the thickness T of bottom portion 308 and thickness U of lower side portion 306 can be individually defined for controlling an amount of electric field reduction at the bottom, side and corner 302 of trench 101. As mentioned above, oxidation on SiC substrate to form relatively thick oxide can be challenging. To address this challenge, the process described herein can form oxide 402 and oxide 602 in different steps, where oxides 402, 602 can be combined to form a thicker oxide such as the thicker portions of oxide region 120. In an embodiment, a thickness T of the bottom portion 308 can be substantially similar to thickness t2. In another embodiment, the thickness T of the bottom portion 308 can vary between approximately 1 nm to 500 nm depending on the duration of the second oxidation process. A thickness U of the lower side portion 306 can vary between approximately 1 nm to 500 nm depending on the duration of the second oxidation process.

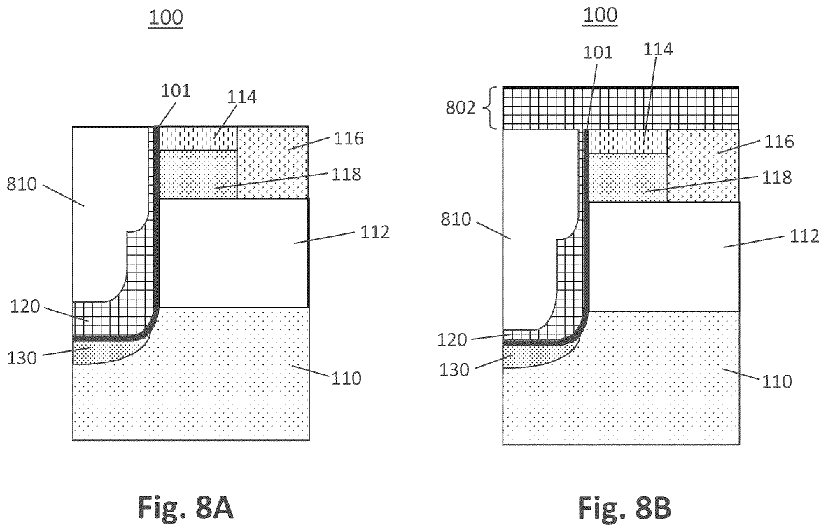

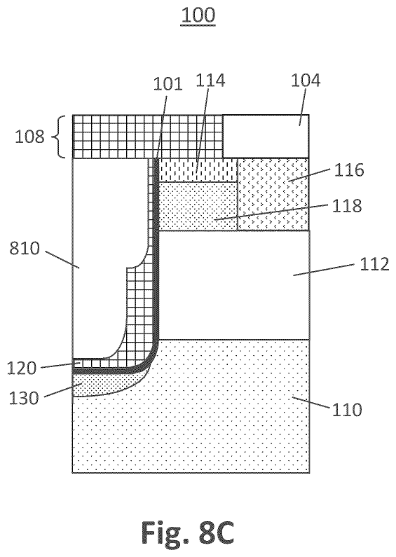

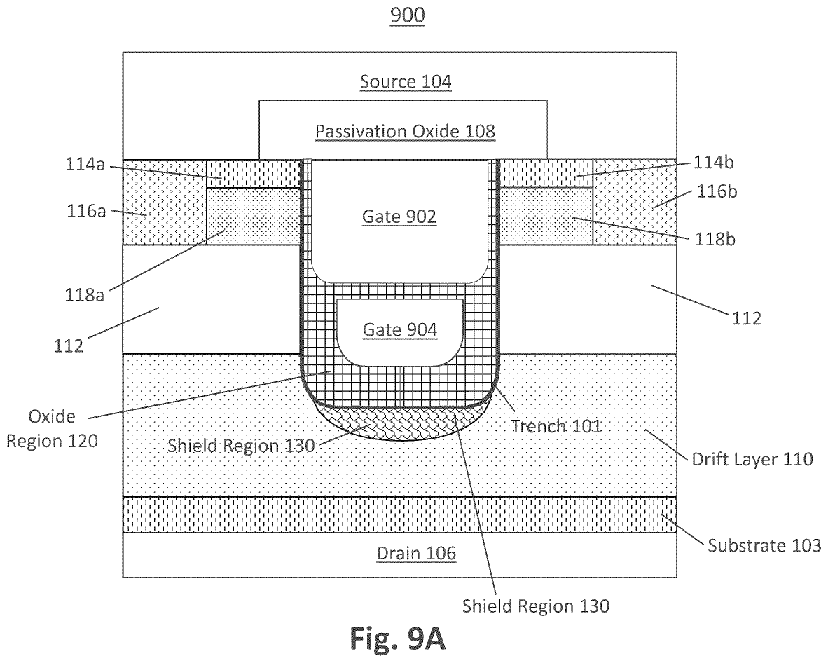

In FIG. 8A, a conductive material 810, such as polysilicon, can be deposited within trench 101 on top of oxide region 120. Although not depicted in the figures, the conductive material 810 can also be deposited on top of first doped region 114 and second doped region 116. In such cases, the conductive material 810 can be etched such that parts of conductive material 810 on top of first doped region 114 and second doped region 116 can be removed, and a top of the remaining of conductive material 810 can be aligned with the top of first doped region 114 and second doped region 116, as shown in FIG. 8A.

In FIG. 8B, additional layer of oxide 802 can be formed on top of conductive material 810 by oxidation. Oxide 802 can be, for example, high-quality oxide that has relatively superior properties compared to other oxides in terms of purity, stability, or specific functional characteristics. The layer of oxide 802 can be formed by oxides such as, for example, SiO₂. In FIG. 8C, the additional layer of oxide 802 can be etched to shape the passivation oxide 108 shown in FIG. 1. After the etching, source 104 can be added.

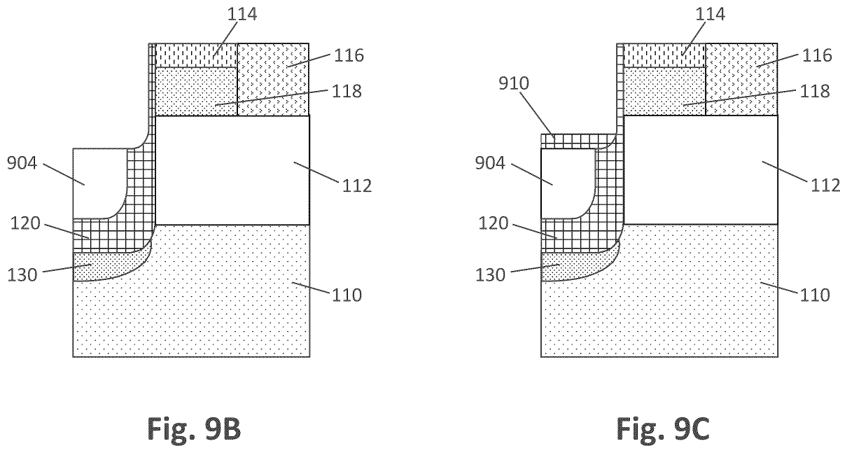

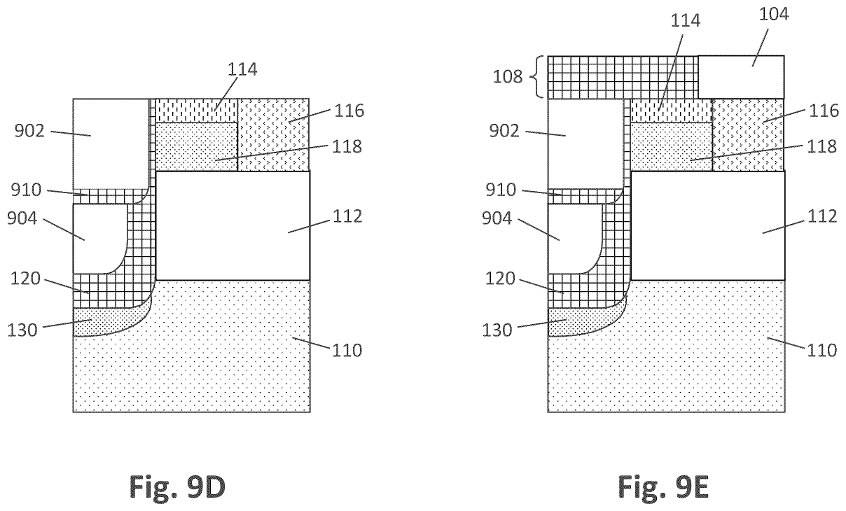

FIG. 9A illustrates another example of a two-step oxide trench Silicon Carbide MOSFET in one embodiment. Descriptions of FIG. 9A can reference components shown in FIG. 1 to FIG. 8B. In one embodiment, FIG. 9A shows one whole unit, or one cell, of a device 900 that implements a SiC trench MOSFET having a split gate arrangement along with the oxide region 120 and the shield region 130 described herein. Device 900 can be a split gate trench MOSFET including at least two gate electrodes 902, 904. Oxide region 120 can be disposed between gates 902, 904 and trench 101. In another embodiment, device 900 shown in FIG. 9A can implement a SiC trench MOSFET having a shield gate arrangement along with the oxide region 120 and the shield region 130 described herein, such that gate electrode 904 can serve as a shield and can have a different doping concentration from gate electrode 902. FIG. 9B to FIG. 9E illustrate a series of steps in a manufacturing process of device 900.

FIG. 9B shows a step that follows FIG. 8A. In FIG. 9B, the conductive material 710 can be etched such that parts of conductive material 710 on top of first doped region 114 and second doped region 116, and some parts that are in trench 101, can be removed. The remainder of conductive material 710 forms gate 904. In FIG. 9C, a layer of oxide (hereinafter “oxide”) 910 can be formed on top of gate 904 by oxidation. Oxide 910 can be, for example, SiO₂. In FIG. 9D, conductive material forming gate 902 can be deposited on oxide 910. In FIG. 9E, the additional layer of oxide 802 can be added on top of the entire stack shown in FIG. 9D to form the passivation oxide 108 and source 104 shown in FIG. 9A.

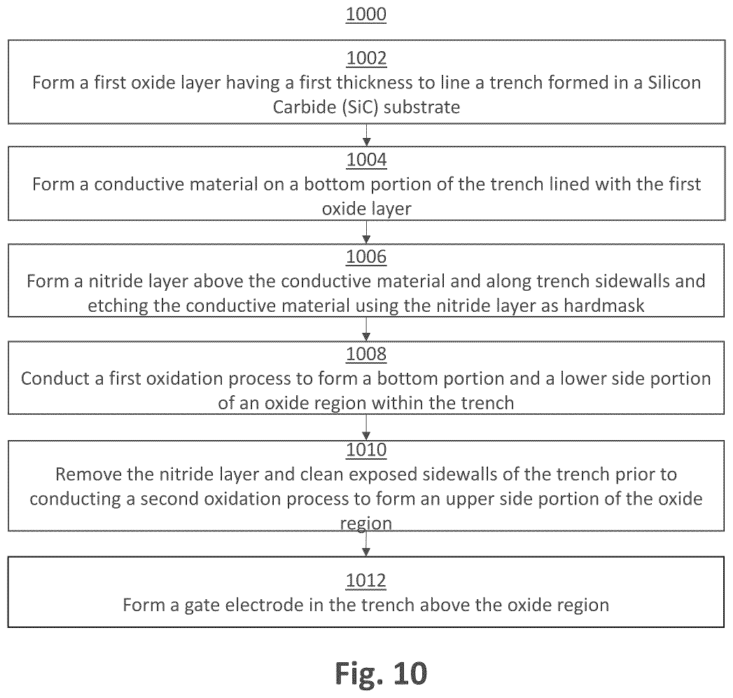

FIG. 10 is a flow diagram illustrating a process to manufacture a two-step oxide trench Silicon Carbide MOSFET in one embodiment. Process 1000 in FIG. 10 can be performed to manufacture semiconductor devices, such as device 100 and/or device 900 described herein. An example process may include one or more operations, actions, or functions as illustrated by one or more of blocks 1002, 1004, 1006, 1008, 1010 and/or 1012. Although illustrated as discrete blocks, various blocks may be divided into additional blocks, combined into fewer blocks, eliminated, performed in different order, or performed in parallel, depending on the desired implementation.

Process 1000 can begin at block 1002. At block 1002, a first oxide layer having a first thickness can be formed to line a trench formed in a Silicon Carbide (SiC) substrate. In one embodiment, a shield region can be formed underneath the trench prior to forming the first oxide layer. A width of the shield region can be less than or equal to a width of the trench. The shield region can be non-overlapping with a sidewall of the trench.

Process 1000 can proceed from block 1002 to block 1004. At block 1004, a conductive material, such as polysilicon, can be formed on a bottom portion of the trench lined with the first oxide layer.

Process 1000 can proceed from block 1004 to block 1006. At block 1006, a nitride layer can be formed above the conductive material and along sidewalls of the trench not covered by the conductive material. The nitride layer can be used as a hard mask to etch the conductive material. Using the nitride layer as hardmask to etch the conductive material results in a remaining portion of the conductive material having a thickness similar to a thickness of the nitride layer.

Process 1000 can proceed from block 1006 to block 1008. At block 1008, a first oxidation process can be conducted to form a bottom portion and a lower side portion of an oxide region within the trench.

Process 1000 can proceed from block 1008 to block 1010. At block 1010, the nitride layer can be removed and exposed sidewalls of the trench can be cleaned prior to conducting a second oxidation process to form an upper side portion of the oxide region. In an embodiment, the oxide region includes the bottom portion, the lower side portion and the upper side portion. A thickness of the bottom portion is greater than a thickness of the upper side portion, and a thickness of the lower side portion is greater than the thickness of the upper side portion. The oxide region lines different portions of the trench with different oxide thickness. The thickness of the bottom portion of the oxide region is a combination of the first thickness and a thickness of a horizontal portion of the remaining portion of the conductive material prior to being oxidized, the thickness of the lower side portion is the combination of the first thickness and a thickness of a vertical portion of the remaining portion of the conductive material prior to being oxidized, and the thickness of the upper side portion is determined by a duration of the second oxidation process.

Process 1000 can proceed from block 1010 to block 1012. At block 1012, a gate electrode can be formed in the trench lined with the oxide region. In one embodiment, a second oxide layer can be formed on the gate electrode. Another gate electrode can be formed on top of the second oxide layer. A passivation oxide layer can be formed on said another gate electrode.

### EXAMPLES

Example 1. A method of forming a semiconductor device, comprising:
forming a first oxide layer having a first thickness to line a trench formed in a Silicon Carbide (SiC) substrate;
forming a conductive material on a bottom portion of the trench lined with the first oxide layer;
forming a nitride layer above the conductive material and along sidewalls of the trench; using the nitride layer as hardmask, etching the conductive material;
conducting a first oxidation process on a remaining portion of the conductive material to form a bottom portion and a lower side portion of an oxide region within the trench;
removing the nitride layer and cleaning exposed sidewalls of the trench;
conducting a second oxidation process on the exposed sidewalls of the trench to form an upper side portion of the oxide region; and
forming a gate electrode in the trench lined with the oxide region.

Example 2. The method according to Example 1, further comprising:
forming a shield region underneath the trench prior to forming the first oxide layer.

Example 3. The method according to Example 2, wherein a width of the shield region is less than or equal to a width of the trench.

Example 4. The method according to Example 2, wherein the shield region is non-overlapping with a sidewall of the trench.

Example 5. The method according to Example 1, wherein using the nitride layer as hardmask to etch the conductive material results in the remaining portion of the conductive material having a thickness similar to a thickness of the nitride layer.

Example 6. The method according to Example 1, wherein:
the oxide region comprises the bottom portion, the lower side portion and the upper side portion;
a thickness of the bottom portion is greater than a thickness of the upper side portion; and
thickness of the lower side portion is greater than the thickness of the upper side portion.

Example 7. The method according to Example 6, wherein:
the thickness of the bottom portion is a combination of the first thickness and a thickness of a horizontal portion of the remaining portion of the conductive material;
the thickness of the lower side portion is the combination of the first thickness and a thickness of a vertical portion of the remaining portion of the conductive material; and
the thickness of the upper side portion is determined by a duration of the second oxidation process.

Example 8. The method according to Example 1, further comprising:
forming a second oxide layer on the gate electrode;
forming another gate electrode on top of the second oxide layer; and
forming a passivation oxide layer on said another gate electrode.

Example 9. A method of forming a semiconductor device, comprising:
forming a semiconductor substrate of a first conductivity type, wherein the semiconductor substrate is formed by Silicon Carbide (SiC);
forming a drift region of the first conductivity type in the semiconductor substrate;
forming a channel of a second conductivity type opposite to the first conductivity type of the drift region;
forming a source region of the first conductivity type, the source region being above the channel;
forming a trench adjacent to the channel, the trench reaching the drift region;
forming an oxide region within the trench, the oxide region lining sidewalls of the trench, wherein:
   the oxide region comprises a bottom portion, a lower side portion and an upper side portion;
   a thickness of the bottom portion is greater than a thickness of the upper side portion; and
   a thickness of the lower side portion is greater than the thickness of the upper side portion;
forming a gate electrode within the trench lined with the oxide region; and
forming a shield region of the second conductivity type in contact with the bottom portion of the trench, wherein a width of the shield region is less than or equal to a width of the trench.

Example 10. The method according to Example 9, wherein the lower side portion of the oxide region is in contact with the upper side portion of the oxide region.

Example 11. The method according to Example 9, wherein the shield region is non-overlapping with a sidewall of the trench.

Example 12. The method according to Example 9, wherein the drift region is in contact with at least a part of the upper side portion of the oxide region and at least a part of the lower side portion of the oxide region.

Example 13. The method according to Example 9, wherein a thickness of the bottom portion of the oxide region is in a range of 1 nm to 500 nm.

Example 14. The method according to Example 9, wherein a thickness of the lower side portion of the oxide region is in a range of 1 nm to 500 nm.

Example 15. The method according to Example 9, wherein an impurity concentration of the shield region is less than an impurity concentration of the channel.

Example 16. The method according to Example 9, wherein an impurity concentration of the shield region is in a range of 1×10¹⁵ cm⁻³ to 5×10¹⁷ cm⁻³.

Example 17. A method of forming a semiconductor device, comprising:
forming a semiconductor substrate of a first conductivity type, wherein the semiconductor substrate is formed by Silicon Carbide (SiC);
forming a drift region of the first conductivity type in the semiconductor substrate;
forming a channel of a second conductivity type opposite to the first conductivity type of the drift region;
forming a source region of the first conductivity type above the channel;
forming a trench adjacent to the channel, the trench reaching the drift region;
forming an oxide region within the trench, the oxide region lining sidewalls of the trench, wherein:
   the oxide region comprises a bottom portion, a lower side portion and an upper side portion;
   a thickness of the bottom portion is greater than a thickness of the upper side portion; and
   a thickness of the lower side portion is greater than the thickness of the upper side portion;
forming at least one gate electrode within the trench lined with the oxide region; and
forming a shield region of the second conductivity in contact with the bottom portion of the trench, wherein a width of the shield region is less than or equal to a width of the trench.

Example 18. The method according to Example 16, wherein the lower side portion of the oxide region is in contact with the upper side portion of the oxide region.

Example 19. The method according to Example 16, wherein the shield region is non-overlapping with a sidewall of the trench.

Example 20. The method according to Example 16, wherein the drift region is in contact with at least a part of the upper side portion of the oxide region and at least a part of the lower side portion of the oxide region.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The disclosed embodiments of the present invention have been presented for purposes of illustration and description but are not intended to be exhaustive or limited to the invention in the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A semiconductor device comprising:
a semiconductor substrate of a first conductivity type, wherein the semiconductor substrate is formed by Silicon Carbide (SiC);
a drift region of the first conductivity type formed on the semiconductor substrate;
a channel of a second conductivity type opposite to the first conductivity type formed on the drift region;
a source region of the first conductivity type formed on the channel;
a trench that penetrates through the source region and the channel and reaches the drift region;
an oxide region that lines the trench, wherein:
the oxide region comprises a bottom portion, a lower side portion and an upper side portion;
a thickness of the bottom portion is greater than a thickness of the upper side portion; and
a thickness of the lower side portion is greater than the thickness of the upper side portion;
a gate electrode formed in the trench lined with the oxide region; and
a shield region of the second conductivity type in contact with the bottom portion of the trench and a width of the shield region is at most equal a width of the trench.

2. The semiconductor device according to claim 1, wherein the lower side portion of the oxide region is in contact with the upper side portion of the oxide region.

3. The semiconductor device according to claim 1, wherein the shield region is non-overlapping with a sidewall of the trench.

4. The semiconductor device according to claim 1, wherein the drift region is in contact with at least a part of the upper side portion of the oxide region and at least a part of the lower side portion of the oxide region.

5. The semiconductor device according to claim 1, wherein a thickness of the bottom portion of the oxide region is in a range of 1 nm to 500 nm.

6. The semiconductor device according to claim 1, wherein a thickness of the lower side portion of the oxide region is in a range of 1 nm to 500 nm.

7. The semiconductor device according to claim 1, wherein an impurity concentration of the shield region is less than an impurity concentration of the channel.

8. The semiconductor device according to claim 1, wherein an impurity concentration of the shield region is in a range of 1×10¹⁵ cm⁻³ to 5×10¹⁷ cm⁻³.

9. A semiconductor device comprising:
a semiconductor substrate of a first conductivity type, wherein the semiconductor substrate is formed by Silicon Carbide (SiC);
a drift region of the first conductivity type formed on the semiconductor substrate;
a channel of a second conductivity type opposite to the first conductivity type formed on the drift region;
a source region of the first conductivity type formed on the channel;
a trench that penetrates through the source region and the channel and reaches the drift region;
an oxide region that lines the trench, wherein:
the oxide region comprises a bottom portion, a lower side portion and an upper side portion;
a thickness of the bottom portion is greater than a thickness of the upper side portion; and
a thickness of the lower side portion is greater than the thickness of the upper side portion;
at least one gate electrode formed in the trench lined with the oxide region; and
a shield region of the second conductivity type in contact with the bottom portion of the trench and a width of the shield region is at most equal to a width of the trench.

10. The semiconductor device according to claim 9, wherein the lower side portion of the oxide region is in contact with the upper side portion of the oxide region.

11. The semiconductor device according to claim 9, wherein the shield region is non-overlapping with a sidewall of the trench.

12. The semiconductor device according to claim 9, wherein the drift region is in contact with at least a part of the upper side portion of the oxide region and at least a part of the lower side portion of the oxide region.

13. A method of forming a semiconductor device, comprising:
forming a first oxide layer having a first thickness to line a trench formed in a Silicon Carbide (SiC) substrate;
forming a conductive material on a bottom portion of the trench lined with the first oxide layer;
forming a nitride layer above the conductive material and along sidewalls of the trench;
using the nitride layer as hardmask to etch the conductive material;
conducting a first oxidation process on a remaining portion of the conductive material to form a bottom portion and a lower side portion of an oxide region within the trench;
removing the nitride layer;
cleaning exposed sidewalls of the trench;
conducting a second oxidation process on the exposed sidewalls of the trench to form an upper side portion of the oxide region; and
forming a gate electrode in the trench lined with the oxide region.

14. The method of claim 13, further comprising forming a shield region underneath the trench prior to forming the first oxide layer.

15. The method of claim 14, wherein a width of the shield region is less than or equal to a width of the trench.

16. The method of claim 14, wherein the shield region is non-overlapping with a sidewall of the trench.

17. The method of claim 13, wherein using the nitride layer as hardmask to etch the conductive material results in the remaining portion of the conductive material having a thickness similar to a thickness of the nitride layer.

18. The method of claim 13, wherein:
the oxide region comprises the bottom portion, the lower side portion and the upper side portion;
a thickness of the bottom portion is greater than a thickness of the upper side portion; and
a thickness of the lower side portion is greater than the thickness of the upper side portion.

19. The method of claim 18, wherein:
the thickness of the bottom portion is a combination of the first thickness and a thickness of a horizontal portion of the remaining portion of the conductive material;
the thickness of the lower side portion is the combination of the first thickness and a thickness of a vertical portion of the remaining portion of the conductive material; and
the thickness of the upper side portion is determined by a duration of the second oxidation process.

20. The method of claim 13, further comprising:
forming a second oxide layer on the gate electrode;
forming another gate electrode on top of the second oxide layer; and
forming a passivation oxide layer on said another gate electrode.
